(19) United States
(12) Patent Application Publication
(10) Pub. No.: US 2024/0333197 A1
(43) Pub. Date: Oct. 3, 2024

(54) THERMOPHOTOVOLTAIC AND RADIATION ENERGY CONVERSION SYSTEMS

(71) Applicant: mPower Technology, Inc., Albuquerque, NM (US)

(72) Inventor: Murat Okandan, Albuquerque, NM (US)

(73) Assignee: mPower Technology, Inc., Albuquerque, NM (US)

(21) Appl. No.: 18/579,827

(22) PCT Filed: Jul. 14, 2022
(86) PCT No.: PCT/US2022/037187

§ 371 Date: Jan. 16, 2024

Related U.S. Application Data
(60) Provisional application No. 63/221,880, filed on Jul. 14, 2021.

(51) Int. Cl. H02S 10/30

(52) U.S. Cl. CPC H02S 10/30

(57) ABSTRACT

Photovoltaic systems and methods for illuminating photovoltaic cells with light just above the cell bandgap. One or more reflectors reflect light incident on the cells that is outside a desired wavelength range, thereby increasing the efficiency of the system. Energy that is available from radioactive decay products, such as fission fragments, electrons, protons, and high energy photons can also be converted to generate light in the desired wavelength range to efficiently couple into the photovoltaic devices. Silicon photovoltaic cells can be used, unlike the complex multi-junction photovoltaic cells of most systems, which also require extensive and costly manufacturing processes.

### CROSS-REFERENCE TO RELATED APPLICATIONS

This application claims priority to and the benefit of the filing of U.S. Provisional Patent Application No. 63/221,880, entitled “THERMOPHOTOVOLTAIC AND RADIATION ENERGY CONVERSION SYSTEMS”, filed on Jul. 14, 2021, the entirety of which is incorporated herein by reference.

### BACKGROUND OF THE INVENTION

### Field of the Invention (Technical Field)

The present invention is related to fabrication, assembly, integration and operation of low cost, high performance thermo-photovoltaic and radiation based energy conversion systems, thermal management systems, sublimated material management and customized photovoltaic cell arrays with applications in energy generation, storage and energy transfer.

### BACKGROUND ART

Note that the following discussion may refer to a number of publications and references. Discussion of such publications herein is given for more complete background of the scientific principles and is not to be construed as an admission that such publications are prior art for patentability determination purposes.

Many thermophotovoltaic (TPV) energy systems have been proposed and developed utilizing multi-junction cells that utilize multiple bandgap materials stacked on top of each other (such as InGaP, GaAs and others) as well as single junction cells. In these systems, a heat source generates mostly infrared radiation and some visible wavelength light (photons) which are then collected and converted into electricity by a photovoltaic device. These systems have focused on harvesting all of the incident photons that are above the bandgap of the solar cells and accepting the thermalization loss that happens when a photon that has higher energy than the bandgap of the cell is absorbed and the difference between the bandgap and the energy of the photon is lost as heat. For example, when a 3 eV photon is absorbed in a 1 eV bandgap material, 2 eV of the energy is lost as heat in the device. For photons whose energies are below the bandgap, a reflector is used that reflects these photons back to the source and therefore ‘recycles’ that energy back into the storage element. This reflector is usually placed behind the cell, which forces the below-bandgap photons to travel through the photovoltaic cell and could lead to absorption of these photons by the free carriers that are in the cell, leading to a reduction in the overall efficiency of the system.

An additional concern with multi-junction compound semiconductor photovoltaic cells (made from GaAs and other III-V materials) is the high cost of production and lower available volume of product. To provide the extremely high production and deployment volumes (many hundreds of GW worth of cells) needed for storage of renewable energy, low cost and ultra-high volume production capable photovoltaic cell structure, processing and substrate material are critical.

There have been proposals to use liquid semiconducting material systems to convert the energy of the radiation products directly into electrical energy output. However, these systems have not been very stable and manufacturable. Although the liquid state of the semiconducting material provides a great advantage in mitigating displacement damage and other structural issues due to radiation damage, maintaining stable electronic properties and contacts to harvest electrical current (and therefore produce power) have been particularly challenging.

### SUMMARY OF THE INVENTION (DISCLOSURE OF THE INVENTION)

An embodiment of the present invention is a photovoltaic system comprising a light source; a plurality of photovoltaic cells; a first reflector tuned to reflect light having a wavelength lower than a bandgap wavelength range back to the light source; and a second reflector tuned to reflect light having a wavelength higher than the bandgap wavelength range; wherein the first reflector and the second reflector are positioned between the photovoltaic cells and the light source. The photovoltaic cells preferably comprise silicon, in which case the bandgap wavelength range is preferably about 800 nm to about 1050 nm, or alternatively about 850 nm to about 950 nm. The resistivity of the photovoltaic cells is preferably less than approximately 0.1 ohm.cm. The photovoltaic cells are preferably singulated and are preferably each between approximately 25 mm² and approximately 25 cm² in area. The first reflector and/or the second reflector are optionally formed as separate pieces, each piece corresponding to a singulated photovoltaic cell. The photovoltaic system optionally comprises a screen configured to block material sublimated or evaporated from the light source from depositing on at least one of the reflectors. The screen is preferably transparent to light within the bandgap wavelength range. The photovoltaic system of preferably further comprises a thermal management system, which preferably maintains a temperature of the photovoltaic cells below approximately 10° C. The first reflector and/or the second reflector preferably comprise a dielectric mirror stack. The first reflector and/or the second reflector are optionally formed on a coverlayer, which preferably comprises glass. The first reflector is preferably on a surface of the coverlayer facing the light source. A single reflector optionally comprises both the first reflector and the second reflector. The photovoltaic cells are preferably configured in a series-parallel network. The light source optionally comprises a source material which is heated and/or radioactive. The source material optionally comprises a thermophotovoltaic emitter. The light source optionally comprises a conversion material configured to convert one or more types of radiation products emitted by the source material to light. The conversion material preferably comprises a configuration selected from the group consisting of fluorescent molecules or atoms embedded in a glass or ceramic matrix, powder, thin film, layer, conversion material surrounding the source material, powder suspended in a liquid, gaseous, or fluid environment, and conversion material embedded in a waveguide. Wavelengths of the converted light are optionally approximately all within the bandgap wavelength range. The photovoltaic cells are preferably not multi-junction cells.

Another embodiment of the present invention is a method of illuminating photovoltaic cells, the method comprising generating light for illuminating a plurality of photovoltaic cells with light; and reflecting light having a wavelength outside a bandgap wavelength range before the light reaches the photovoltaic cells. The photovoltaic cells preferably comprise silicon, in which case the bandgap wavelength range is preferably about 800 nm to about 1050 nm or alternatively about 850 nm to about 950 nm. The method preferably comprises maintaining the photovoltaic cells at a temperature below approximately 10° C. The method preferably comprises configuring the photovoltaic cells in a series-parallel network. The generating step optionally comprises using a thermophotovoltaic source. The generating step alternatively comprises converting radiation products emitted from a heated and/or radioactive source to light. The wavelengths of the converted light are preferably approximately all within the bandgap wavelength range. The photovoltaic cells are preferably not multi-junction cells. The method preferably comprises blocking sublimated or evaporated material produced by the source from being transported to the photovoltaic cells. The blocking step is preferably performed with approximately no attenuation of light within the bandgap wavelength range.

Another embodiment of the present invention is a photovoltaic system comprising a radiation product source that is heated and/or radioactive; a conversion material configured to convert one or more types of radiation products emitted by the light source to light; and a plurality of photovoltaic cells; wherein wavelengths of the converted light are approximately all within a bandgap wavelength range. The conversion material comprises a configuration selected from the group consisting of fluorescent molecules or atoms embedded in a glass or ceramic matrix, powder, thin film, layer, conversion material surrounding the source material, powder suspended in a liquid, gaseous, or fluid environment, and conversion material embedded in a waveguide. The photovoltaic cells preferably comprise silicon, in which case the bandgap wavelength range is preferably about 800 nm to about 1050 nm, or alternatively about 850 nm to about 950 nm. The photovoltaic cells are preferably not multi-junction cells. The plurality of photovoltaic cells are preferably configured in a series-parallel network. The photovoltaic system preferably comprises a screen configured to block material sublimated or evaporated from the light source from depositing on at least one of the reflectors. The screen is preferably transparent to light within the bandgap wavelength range. The photovoltaic system preferably comprises a thermal management system, which preferably maintains a temperature of the photovoltaic cells below approximately 10° C.

Another embodiment of the present invention is a method of illuminating photovoltaic cells, the method comprising generating radiation products from a heated and/or radioactive source; converting the radiation products to light; and illuminating a plurality of photovoltaic cells with the light; wherein wavelengths of the converted light are approximately all within a bandgap wavelength range. The conversion material preferably comprises a configuration selected from the group consisting of fluorescent molecules or atoms embedded in a glass or ceramic matrix, powder, thin film, layer, conversion material surrounding the source, powder suspended in a liquid, gaseous, or fluid environment, and conversion material embedded in a waveguide. The photovoltaic cells preferably comprise silicon, in which case the bandgap wavelength range is preferably about 800 nm to about 1050 nm, or alternatively about 850 nm to about 950 nm. The photovoltaic cells are preferably not multi-junction cells. The method preferably comprises maintaining the photovoltaic cells at a temperature below approximately 10° C. The method preferably comprises configuring the photovoltaic cells in a series-parallel network. The method optionally comprises blocking sublimated or evaporated material produced by the source from being transported to the photovoltaic cells. The blocking step is preferably performed with approximately no attenuation of light within the bandgap wavelength range.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated into and form a part of the specification, illustrate the practice of embodiments of the present invention and, together with the description, serve to explain the principles of the invention. The drawings are only for the purpose of illustrating certain embodiments of the invention and are not to be construed as limiting the invention. In the drawings:

FIG. 1 shows a cell and reflector arrangement that has the bandpass function implemented at the front surface of the coverlayer.

FIG. 2 shows a cell and reflector arrangement that has the high-pass function implemented at the front surface and low-pass function implemented at the back surface of the coverlayer.

FIG. 3 shows a cell and reflector arrangement that has the high-pass function implemented at the front surface of the coverlayer and the low-pass function implemented at the cell front surface.

FIG. 4 shows the bandgap of silicon and the slightly above-bandgap portion of the light being absorbed in the cell.

FIG. 5 shows a series-parallel interconnect configuration of the cells.

FIG. 6 shows a radioactive source with a conversion layer and photovoltaic cell.

FIG. 7 shows a radioactive source with embedded conversion layer/light guide features that guide the light to a photovoltaic cell.

FIG. 8 shows a configuration where radioactive source(s) and conversion material are embedded in a structure or are in powder form suspended inside a container or other matrix material, and a photovoltaic cell.

FIG. 9 shows a radioactive source and a conversion layer that is using both emitted electrons and other particles (for example, alphas) to generate light, and a photovoltaic cell that is converting the light into electrical energy output.

FIG. 10 shows a configuration where the conversion layer is coated around a radioactive source, and the light coming from the conversion layer is captured by the photovoltaic cell and converted into electrical output.

### DETAILED DESCRIPTION OF EMBODIMENTS OF THE INVENTION

Silicon photovoltaic devices have been designed for direct solar input and concentrator applications for many years, and now 1-sun solar systems are being produced and deployed at >100 GW/yr volumes. While previous TPV systems, using either silicon or III-V photovoltaic cells, focused on harvesting all the photons above the bandgap of the cell, embodiments of the present invention utilize a limited portion of that spectrum, just above the bandgap of the silicon cell, therefore limiting the losses encountered in the thermalization of the photons as much as possible, while recycling the higher energy above-bandgap photons as well as the below-bandgap photons. When these photons are absorbed by the source, the energy is redeposited into the source, preventing energy loss in the form of waste heat that would have to be removed by the cooling system for the overall assembly. As used throughout the specification and claims, the term “bandgap wavelength range” means from approximately at the bandgap wavelength of the photovoltaic material to approximately 20% below the bandgap wavelength of the photovoltaic material. As used throughout the specification and claims, the term “light” means electromagnetic radiation. Reflector layers are preferably deposited on a coverlayer, for example comprising glass, that is above the cell, and have a desired band-pass function that can be tuned to optimize the system efficiency. For example, a band-pass filter of 850 nm to 950 nm or 950 nm to 1050 nm would allow photons that are slightly above the 1.1 eV bandgap of silicon to enter the cell. To maximize collection of the photo-generated carriers while minimizing any potential losses due to recombination of photogenerated carriers in the cell or due to the series resistance in the cell or interconnects between the cells, the doping level of the substrate is preferably appropriately adjusted, such as to provide 0.1 Ohm.cm or lower substrate resistivity, and the n-type and p-type contacts are preferably placed closely to prevent current crowding at the contacts or similar issues. Cells are preferably singulated and interconnected in a series-parallel configuration to achieve a high voltage, low current circuit layout, with each individual cell preferably having a size in the approximate 5 mm×5 mm to 5 cm×5 cm range. This configuration also provides resilience against any imperfections in the array such as slight mismatches among the cells or potential shorts or opens that might occur during the manufacturing, shipment, assembly, delivery, launch and/or operation of the system.

In conventional TPV systems, due to the high temperature of the source, some amount of material eventually sublimates from the source or other materials in the system. Deposition of these sublimated or evaporated materials onto the solar cells or any other element in the optical path causes scattering and/or absorption of light, and therefore reduces, and eventually ends, power production. In embodiments of the present invention, a roller system with a screen material is preferably used to capture these materials that would otherwise block light transmission. The screen material is preferably chosen to allow the desired wavelengths of light to be transmitted, and the screen continuously or periodically moves in and out of the main power generation chamber to have the deposited material removed. Screen material can be a thin glass, a polymeric layer, or a combination of several material types (glass, polymeric, ceramic materials embedded in polymer, etc.). The screen can be continuous so that when a portion is out of the main chamber, additional screen material is still in the main chamber to allow continuous power generation. The deposited material can be removed from the screen by a number of methods, such as chemical etching, sputtering, laser ablation or mechanical abrasion. The screen material can also perform additional functions such as stopping low energy protons, alpha particles, and reflecting certain wavelengths of light back to the source or to the cells. Screen material can be run in both directions to allow multiple use cycles of the screen, with cleaning system potentially available on both sides or on one side of the system. The roller system can be constructed as a cartridge system, so it can be removed and replaced as part of the operational cycle of the system.

In another embodiment, energy in the form of radiation products from a source, such as a thermionic emission source or radioactive source, can be converted to light, preferably in 800 nm to 1050 nm range, by using various techniques such as scintillation, activation/down-conversion cascades, and resonant energy transfer from one atom and/or molecule to another. As used throughout the specification and claims, the term “radiation products” means fission fragments, alpha particles, beta particles, gamma rays, x-rays, electrons, protons, high energy photons, other radiation products, and the like. The radiation products can be captured by a down-conversion layer or medium, such as a film and/or a collection of particles, and that down-conversion layer preferably comprises a combination of elements that then emit light in the desired 800 nm-1050 nm range. This could be a glass or ceramic matrix, array of optical fibers or other similar structures with embedded fluorescent molecules or atoms, which collectively capture the initial energy that is coming from the source and re-emit it in the desired range. Another approach is to use the thermal energy that is deposited into the structure, either by itself in case of thermo-photovoltaics, or in combination with thermal energy and energy transfer from the incident particle from the source and the conversion matrix where the desired light emission is achieved. This emitted light is then captured and converted into delivered power by the photovoltaic elements.

In another embodiment, thermionic emission of electrons is preferably utilized to help in conversion of the energy into desired light output range (for example, about 800 nm to about 1050 nm for coupling to silicon photovoltaic cells). The electrons emitted from the hot source (potentially using the thermal energy provided by the radioactive source and using features such as Spindt tips, Lanthanum hexaboride emitters, etc.) are then incident on a conversion layer, which could emit light just based on the energy provided by these electrons or in combination with the other radiation products emitted by the radioactive source and the thermal energy that is available.

The conversion materials can be in powder form, thin-film form with radioactive materials embedded inside individual particles, layers, or any other form. The radioactive materials can be formed as separate particles or mechanical structures placed in close proximity to conversion layers. For the powder form, these materials can be suspended in vacuum and excited by mechanical means (for example, with an ultrasonic actuator coupled to a section of the assembly that causes the particles to be dispersed into the volume around the source). In another embodiment, particles can be suspended in an gaseous environment and particles can be actuated by mechanical means or by convectional flow of the gaseous medium driven by the thermal gradients in the assembly or pressure driven flows within the assembly or a combination of these. This volume of conversion material suspended and/or dispersed in a fluid medium (liquid, gaseous or supercritical fluid) can also be placed around or throughout the source, for example in a cylindrical flow channel around a cylindrical source geometry, which allows the conversion material to be circulated and maintained in a desired configuration.

In applications where cold temperatures are available, keeping the solar cells at as low of a temperature as possible is desired, since that will improve the efficiency of the photovoltaic energy conversion. For example, for space applications, the photovoltaic cells can be attached to a section that is kept at −50° C.,-150° C., or lower, which reduces thermally generated carriers and therefore the dark current for the cells, producing higher open circuit voltage (Voc) and maximum power point voltage (Vmpp).

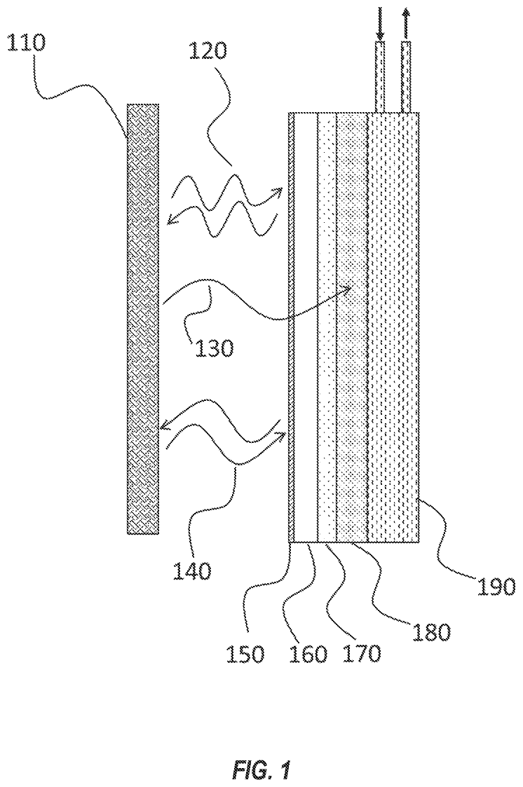

As shown in FIG. 1, light source 110 generates light in a broad wavelength range, including short wavelength range 120, for example 500 nm to 800 nm, mid-wavelength range 130, for example 800 nm to 1050 nm, and in long wavelength range 140, for example longer than 1050 nm. Reflector layer 150, which may comprise a dielectric mirror stack, is preferably formed on coverlayer 160, which may comprise glass. Encapsulant layer 170 with the appropriate index match to coverlayer 160 and photovoltaic cell 180 is preferably used to attach the coverlayer to the photovoltaic cell. The photovoltaic cell may comprise the typical antireflection coating comprising silicon nitride and/or silicon dioxide and the pyramidal texture on its front surface commonly used in terrestrial photovoltaic cells, which will allow mid-wavelength range light 130 to enter and get reflected multiple times and essentially trapped in photovoltaic cell 180, which preferably comprises silicon. The reflected short wavelength range light and long wavelength range light is absorbed by light source 110 and therefore recycled in the system. Light source 110 may comprise a heated material, such as a carbon block or other suitable material. Thermal management layer 190 is preferably attached to photovoltaic cell 180 to keep its temperature low, for example approximately 10° C. or lower, to achieve higher efficiency photovoltaic conversion.

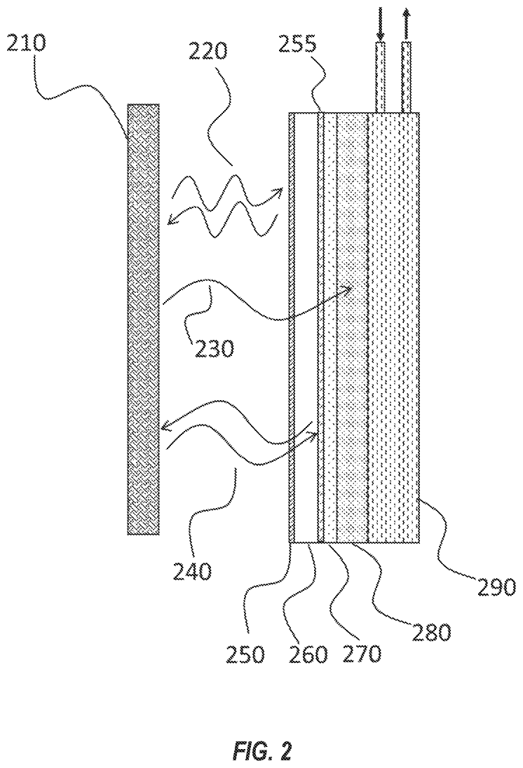

As shown in FIG. 2, light source 210 generates light in a broad wavelength range, including short wavelength range 220, for example 500 nm to 800 nm, mid-wavelength range 230, for example 800 nm to 1050 nm, and in long wavelength range 240, for example longer than 1050 nm. Reflector layer 250, which may comprise a dielectric mirror stack, is preferably formed on coverlayer 260, which may comprise glass. An additional reflector layer 255 is preferably formed on the back surface of coverlayer 260. Encapsulant layer 270 with the appropriate index match to coverlayer 260 and photovoltaic cell 280 is preferably used to attach the coverlayer to the photovoltaic cell. The photovoltaic cell may comprise the usual antireflection coating composed of silicon nitride and/or silicon dioxide and the pyramidal texture on its front surface commonly used in terrestrial photovoltaic cells which will allow mid-wavelength range light 230 to enter and get reflected multiple times and essentially trapped in photovoltaic cell 280, which preferably comprises silicon. Front reflector layer 250 preferably reflects short wavelength range light 220 back to light source 210 and back reflector 255 preferably reflects long wavelength light 240 back to light source 210. The reflected short and long wavelength light is absorbed by light source 210 and therefore recycled in the system. Light source 210 may comprise a heated material, such as a carbon block or other suitable material. Thermal management layer 290 is preferably attached to photovoltaic cell 280 to keep its temperature low, for example approximately 10° C. or lower, to achieve higher efficiency photovoltaic conversion.

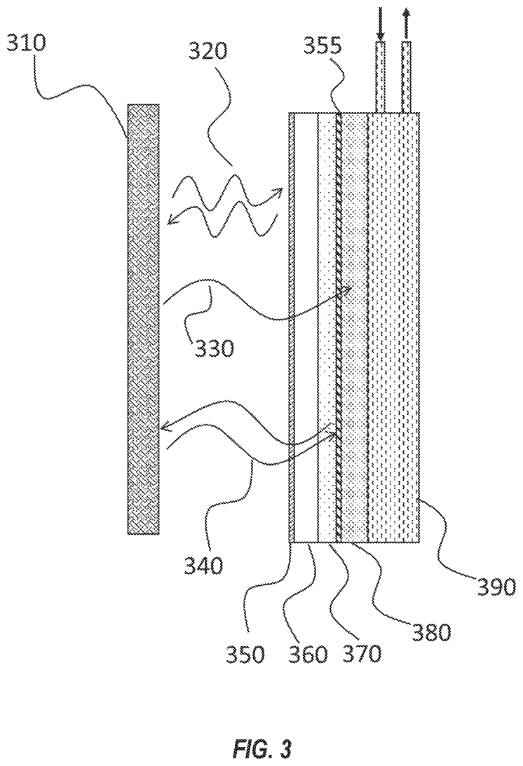

As shown in FIG. 3, light source 310 generates light in a broad wavelength range, including short wavelength range 320, for example 500 nm to 800 nm, mid-wavelength range 330, for example 800 nm to 1050 nm, and in long wavelength range 340, for example longer than 1050 nm. Reflector layer 350, which may comprise a dielectric mirror stack, is preferably formed on coverlayer 360, which may comprise glass. An additional reflector layer 255 is preferably formed on the front surface of photovoltaic cell 280. Encapsulant layer 370 with the appropriate index match to coverlayer 360 and photovoltaic cell 380 is preferably used to attach the coverlayer to the photovoltaic cell. The photovoltaic cell may comprise a multi-layer dielectric antireflection coating comprising silicon nitride and/or silicon dioxide or other dielectric materials and the pyramidal texture on its front surface commonly used in terrestrial photovoltaic cells which will allow mid-wavelength range light 330 to enter and get reflected multiple times and essentially trapped in photovoltaic cell 380, which preferably comprises silicon. Front reflector layer 350 preferably reflects short wavelength range light 320 back to light source 310. Cell surface reflector 355 preferably reflects long wavelength light 340 back to light source 310. The reflected short and long wavelength light is preferably absorbed by light source 310 and therefore recycled in the system. Light source 310 may comprise a heated material, such as a carbon block or other suitable material. Thermal management layer 390 is preferably attached to photovoltaic cell 380 to keep its temperature low, for example approximately 10° C. or lower, to achieve higher efficiency photovoltaic conversion.

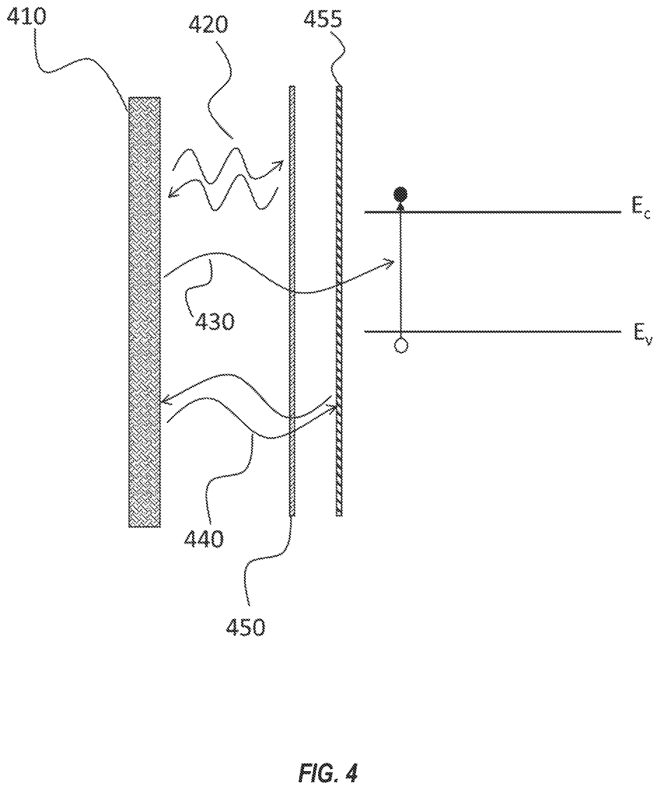

As shown in FIG. 4, in the general case, light source 410 generates light in short wavelength range 420, for example 500 nm to 800 nm, which is preferably reflected back by reflector 450. Long wavelength range light 440, for example longer than 1050 nm, is preferably reflected back by reflector 455. Mid-wavelength range light 430, for example 800 nm to 1050 nm, is preferably absorbed by the photovoltaic cell, which preferably comprises silicon, which leads to the creation of electron hole pairs that are then collected to generate electrical power that is delivered to the external system.

In the above figures, the photovoltaic cell is shown and described as a single cell. However, in some embodiments there are a plurality of photovoltaic cells (as further described elsewhere herein) where the single cell is shown, optionally covered and separated by the encapsulant, corresponding to single sheets of the reflectors or a single coverlayer sheet which comprises the reflector layers and a single thermal management layer.

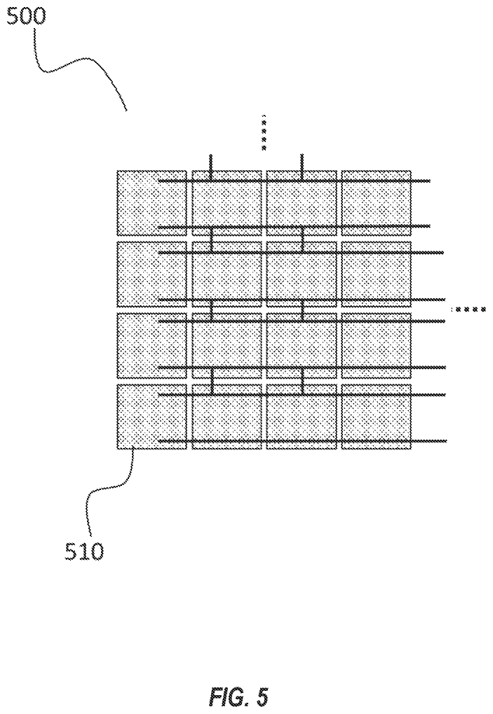

As shown in FIG. 5, a series-parallel network 500 of individual cells 510 are preferably configured to function as the energy conversion system. The cells are preferably sized such that the high voltage, low current configuration can be achieved rapidly, for example by using cells that are 1 cm×1 cm in size. In this example, the cells in each row are connected in parallel, and the rows are connected in series, although other configurations may be used. Even though FIG. 5 shows a square outline for each of the singulated, individual cells 510, they can be arbitrarily shaped and sized, for example hexagons, triangles or other combinations of shapes, as needed to form the structure that fills the light collection area for the energy conversion system.

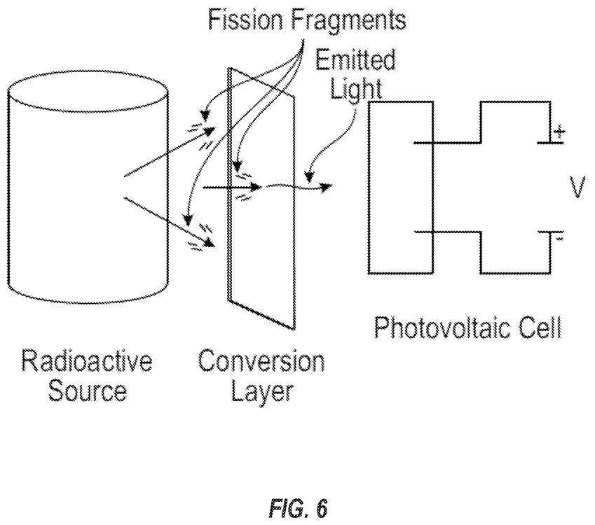

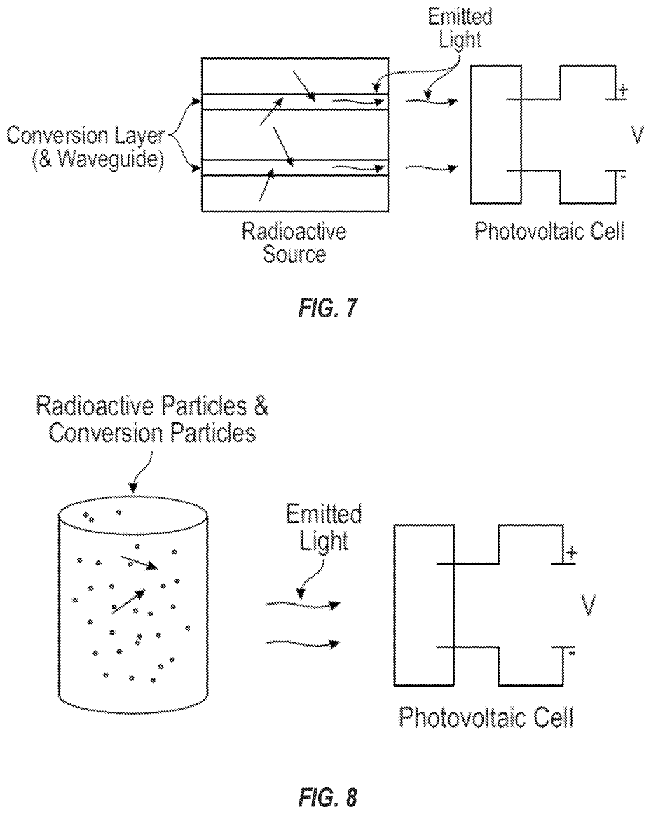

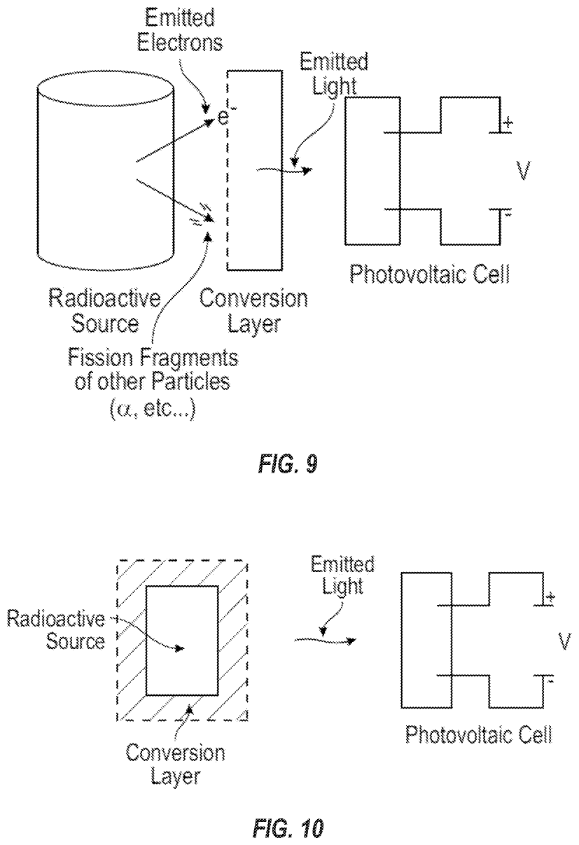

FIGS. 6-10 show different system configurations in which radiation products emitted by a radioactive source are preferably converted into light by a conversion layer. That light is then captured by a photovoltaic cell and converted into electrical power output. For example, electrons emitted by the radioactive source (e.g. through thermionic emission) can be combined with energy deposited into the conversion layer by emissions of other radiation products from the radioactive source and the thermal energy deposited into the conversion layer to achieve the desired light emission in the 800 nm to 1050 nm range for efficient conversion to electrical power output by silicon photovoltaic cells. FIG. 6 shows a radioactive source with a conversion layer and photovoltaic cell. FIG. 7 shows a radioactive source with embedded conversion layer/waveguide features that guide the light to a photovoltaic cell. FIG. 8 shows a configuration where radioactive source(s) and conversion material are embedded in a structure or are in powder form suspended inside a container or other matrix material, and a photovoltaic cell. FIG. 9 shows a radioactive source and a conversion layer that is using both emitted electrons and other particles (for example, alphas) to generate light, and a photovoltaic cell that is converting the light into electrical energy output. FIG. 10 shows a configuration where the conversion layer is coated around a radioactive source, and the light coming from the conversion layer is captured by the photovoltaic cell and converted into electrical output.

Note that in the specification and claims, “about” or “approximately” means within twenty percent (20%) of the numerical amount cited. As used herein, the singular forms “a,” “an,” and “the” include plural referents unless the context clearly dictates otherwise. Thus, for example, reference to “a functional group” refers to one or more functional groups, and reference to “the method” includes reference to equivalent steps and methods that would be understood and appreciated by those skilled in the art, and so forth.

Although the invention has been described in detail with particular reference to the disclosed embodiments, other embodiments can achieve the same results. Variations and modifications of the present invention will be obvious to those skilled in the art and it is intended to cover all such modifications and equivalents. The entire disclosures of all patents and publications cited above are hereby incorporated by reference.

1-35. (canceled)

36. A photovoltaic system comprising:
a radiation product source that is heated and/or radioactive;
a conversion material configured to convert one or more types of radiation products emitted by the light source to light; and
a plurality of photovoltaic cells;
wherein wavelengths of the converted light are approximately all within a bandgap wavelength range.

37. The photovoltaic system of claim 36 wherein the conversion material comprises a configuration selected from the group consisting of fluorescent molecules or atoms embedded in a glass or ceramic matrix, powder, thin film, layer, conversion material surrounding the source material, powder suspended in a liquid, gaseous, or fluid environment, and conversion material embedded in a waveguide.

38. The photovoltaic system of claim 36 wherein the photovoltaic cells comprise silicon.

39. The photovoltaic system of claim 38 wherein the bandgap wavelength range is approximately 800 nm to approximately 1050 nm.

40. The photovoltaic system of claim 39 wherein the bandgap wavelength range is approximately 850 nm to approximately 950 nm.

41. The photovoltaic system of claim 36 wherein the photovoltaic cells are not multi-junction cells.

42. The photovoltaic system of claim 36 wherein the plurality of photovoltaic cells are configured in a series-parallel network.

43. The photovoltaic system of claim 36 comprising a screen configured to block material sublimated or evaporated from the light source from depositing on at least one of the reflectors.

44. The photovoltaic system of claim 43 wherein the screen is transparent to light within the bandgap wavelength range.

45. The photovoltaic system of claim 36 further comprising a thermal management system.

46. The photovoltaic system of claim 45 wherein the thermal management system maintains a temperature of the photovoltaic cells below approximately 10° C.

47. A method of illuminating photovoltaic cells, the method comprising:
generating radiation products from a heated and/or radioactive source;
converting the radiation products to light; and
illuminating a plurality of photovoltaic cells with the light;
wherein wavelengths of the converted light are approximately all within a bandgap wavelength range.

48. The method of claim 47 wherein the conversion material comprises a configuration selected from the group consisting of fluorescent molecules or atoms embedded in a glass or ceramic matrix, powder, thin film, layer, conversion material surrounding the source, powder suspended in a liquid, gaseous, or fluid environment, and conversion material embedded in a waveguide.

49. The method of claim 47 wherein the photovoltaic cells comprise silicon.

50. The method of claim 47 wherein the bandgap wavelength range is approximately 800 nm to approximately 1050 nm.

51. The method of claim 50 wherein the bandgap wavelength range is approximately 850 nm to approximately 950 nm.

52. The method of claim 47 wherein the photovoltaic cells are not multi-junction cells.

53. The method of claim 47 comprising maintaining the photovoltaic cells at a temperature below approximately 10° C.

54. The method of claim 47 comprising configuring the photovoltaic cells in a series-parallel network.

55. The method of claim 47 comprising blocking sublimated or evaporated material produced by the source from being transported to the photovoltaic cells.

56. The method of claim 55 wherein the blocking step is performed with approximately no attenuation of light within the bandgap wavelength range.
